(19) United States
(12) Patent Application Publication
(10) Pub. No.: US 2016/0133337 A1
(43) Pub. Date: May 12, 2016

(54) SHIFT REGISTER UNIT, SHIFT REGISTER, GATE DRIVE CIRCUIT AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei City (CN)

(72) Inventor: Xiaofang GU, Beijing (CN)

(21) Appl. No.: 14/802,070

(22) Filed: Jul. 17, 2015

(30) Foreign Application Priority Data
Nov. 12, 2014 (CN) 201410636035.4

(51) Int. Cl. G11C 19/28

(52) U.S. Cl. CPC G11C 19/28

(57) ABSTRACT

A shift register unit, a shift register, a gate drive circuit and a display device, the shift register unit, comprising: an input module; an output module configured to output a first clock signal of a first clock signal terminal to an output terminal of the shift register unit according to a potential of the pull-up node at an output phase; a reset module configured to pull down the potentials of the pull-up node and the output terminal of the shift register unit according to a reset signal at a reset phase; and a pull-down module configured to pull down the potentials of the pull-up node and the output terminal according to a second clock signal of a second clock signal terminal at a pull-down phase. Compared to the related art, the structure of the shift register unit provided by the present disclosure is simpler.

### FIELD OF THE INVENTION

The present disclosure relates to the display technical field, and in particular to a shift register unit, a shift register, a gate drive circuit and a display device.

### BACKGROUND

The liquid crystal display (LCD) has such advantages as a light weight, thin thickness and low power consumption, etc. and is widely used in such electronic devices as TVs, mobile phones, and monitors, etc.

The LCD is composed of pixel matrixes of such two directions as horizontal and vertical ones. When the LCD is displaying, it outputs a gate scan signal through a gate drive circuit and progressively scans pixels. The drivers of the LCD mainly comprise a gate driver and a data driver. The gate driver converts an input clock signal through a shift register (SR) into an on/off voltage, and sequentially applies it to a gate line of a liquid crystal panel. The shift register (SR) in the gate driver is used for generating a scan signal in scanning the gate line.

FIG. 1 is a schematic diagram of a circuit structure of an existing shift register unit. The circuit is composed of 12 TFTs made of amorphous silicon (i.e., M1˜M12 shown in the figure) and a capacitor. This kind of circuit has a very complicated structure, needs a very large space, and can not meet a requirement for a narrow border.

### SUMMARY OF THE INVENTION

The object of the present disclosure is to provide a shift register unit, a shift register comprising the shift register unit, a gate drive circuit comprising the shift register and a display device comprising the gate drive circuit, so as to simplify the structure of the shift register unit, facilitating design of a narrow border.

In order to achieve the above mentioned object, the present disclosure provides a shift register unit, comprising:

an input module configured to receive an input signal at a precharge phase and outputting the input signal to a pull-up node;

an output module configured to output a first clock signal of a first clock signal terminal to an output terminal of the shift register unit according to a potential of the pull-up node at an output phase;

a reset module configured to pull down the potentials of the pull-up node and the output terminal of the shift register unit according to a reset signal at a reset phase; and

a pull-down module configured to pull down the potentials of the pull-up node and the output terminal according to a second clock signal of a second clock signal terminal at a pull-down phase, wherein the first clock signal terminal only provides the first clock signal of a high level to the output module at the output phase, and the second clock signal terminal only provides the second clock signal of a high level to the pull-down module at the reset phase or the pull-down phase.

Preferably, the pull-down module includes a seventh thin film transistor and an eighth thin film transistor,

the gate of the seventh thin film transistor is connected with the second clock signal terminal, the first electrode of the seventh thin film transistor is connected with the pull-up node, and the second electrode of the seventh thin film transistor is connected with a low level input terminal;

the gate of the eighth thin film transistor is connected with the second clock signal terminal, the first electrode of the eighth thin film transistor is connected with the output terminal of the shift register unit, and the second electrode of the eighth thin film transistor is connected with the low level input terminal.

Preferably, the shift register unit further comprises a third clock signal terminal and a first noise reduction module, which is connected with the third clock signal terminal, the output terminal of the shift register unit and the low level input terminal, configured to pull down the potential of the output terminal of the shift register unit according to a third clock signal of the third clock signal terminal at a noise reduction phase subsequent to the pull-down phase;

wherein the third clock signal terminal only provides the third clock signal of a high level to the first noise reduction module at the noise reduction phase.

Preferably, the first noise reduction module includes a ninth thin film transistor, the gate of the ninth thin film transistor is connected with the third clock signal terminal, the first electrode of the ninth thin film transistor is connected with the output terminal of the shift register unit, and the second electrode of the ninth thin film transistor is connected with the low level input terminal.

Preferably, the shift register unit further comprises a fourth clock signal terminal and a second noise reduction module, which is connected with the fourth clock signal terminal, the pull-up node, the output terminal of the shift register unit and the low level input terminal, configured to pull down the potentials of the pull-up node and the output terminal of the shift register unit according to a fourth clock signal of the fourth clock signal terminal at the pull-down phase, the second clock signal terminal only provides the second clock signal of a high level to the pull-down module at the reset phase, and the fourth clock signal terminal only provides the fourth clock signal of a high level to the second noise reduction module at the pull-down phase.

Preferably, the second noise reduction module includes a fifth thin film transistor and a sixth thin film transistor,

the gate of the fifth thin film transistor is connected with the fourth clock signal terminal, the first electrode of the fifth thin film transistor is connected with the pull-up node, and the second electrode of the fifth thin film transistor is connected with the low level input terminal;

the gate of the sixth thin film transistor is connected with the fourth clock signal terminal, the first electrode of the sixth thin film transistor is connected with the output terminal of the shift register unit, and the second electrode of the sixth thin film transistor is connected with the low level input terminal.

Preferably, the input module includes a first thin film transistor, both the gate and the first electrode of the first thin film transistor are connected with the input terminal of the shift register unit, and the second electrode of the first thin film transistor is connected with the pull-up node.

Preferably, the output module includes a third thin film transistor and a capacitor,

the gate of the third thin film transistor is connected with the pull-up node, the first electrode of the third thin film transistor is connected with the first clock signal terminal, and the second electrode of the third thin film transistor is connected with the output terminal of the shift register unit;

the first terminal of the capacitor is connected with the pull-up node, and the second terminal of the capacitor is connected with the output terminal of the shift register unit.

Preferably, the reset module includes a second thin film transistor and a fourth thin film transistor,

the gate of the second thin film transistor is connected with the reset terminal of the shift register unit, the first electrode of the second thin film transistor is connected with the pull-up node, and the second electrode of the second thin film transistor is connected with the low level input terminal;

the gate of the fourth thin film transistor is connected with the reset terminal of the shift register unit, the first electrode of the fourth thin film transistor is connected with the output terminal of the shift register unit, and the second electrode of the fourth thin film transistor is connected with the low level input terminal.

Accordingly, the present disclosure further provides a shift register, which comprises at least three levels of shift register units which are the shift register units provided by the present disclosure, where in the adjacent three levels of shift register units, the output terminal of the second level shift register unit are connected with the input terminal of the third level shift register unit and the reset terminal of the first level shift register unit, respectively.

Accordingly, the present disclosure further provides a gate drive circuit, which comprises a shift register that comprises the above mentioned shift register unit provided by the present disclosure, where the gate drive circuit further comprises a first clock signal generating line and a second clock signal generating line, where the first clock signal generating line is connected with the first clock signal terminal of the shift register unit, the second clock signal generating line is connected with the second clock signal terminal of the shift register unit, the first clock signal generating line only provides a first clock signal of a high level at an output phase, and the second clock signal generating line only provides a second clock signal of a high level to the shift register unit at a reset phase or a pull-down phase.

Preferably, the shift register unit further comprises a third clock signal terminal and a first noise reduction module, which is connected with the third clock signal terminal, the output terminal of the shift register unit and a low level input terminal, configured to pull down the potential of the output terminal of the shift register unit according to a third clock signal of the third clock signal terminal at a noise reduction phase subsequent to the pull-down phase; and, the gate drive circuit further comprises a third clock signal generating line which is connected with the third clock signal terminal,

wherein, the third clock signal generating line only provides a third clock signal of a high level to the third clock signal terminal at a noise reduction phase.

Preferably, the shift register unit further comprises a fourth clock signal terminal and a second noise reduction module, which is connected with the fourth clock signal terminal, the pull-up node, the output terminal of the shift register unit and the low level input terminal, configured to pull down the potentials of the pull-up node and the output terminal of the shift register unit according to a fourth clock signal of the fourth clock signal terminal at the pull-down phase; and, the gate drive circuit further comprises a fourth clock signal generating line which is connected with the fourth clock signal terminal,

the second clock signal generating line only provides a second clock signal of a high level to the second clock signal terminal at a reset phase, and the fourth clock signal generating line only provides a fourth clock signal of a high level to the fourth clock signal terminal at a pull-down phase.

Accordingly, the present disclosure further provides a display device which comprises the gate drive circuit provided by the present disclosure.

In the present disclosure, the second clock signal terminal can directly control the pull-down module, so the function of the shift register unit can be achieved only by adjusting the first clock signal and the second clock signal, allowing the pull-down module to have a function that the pull-down can be performed only by having a simple structure, thus allowing the shift register to have a relatively simple structure, and thereby achieving the design of a narrow border. Compared to the related art, the time for the first clock signal and the second clock signal to provide high levels is shortened, thus allowing the on time of the thin film transistor in the shift register unit to be shortened, the life cycle to be lengthened and the threshold voltage drifting phenomenon of the thin film transistor to be mitigated.

### BRIEF DESCRIPTION OF THE DRAWINGS

The accompanying drawings, which are included to provide a further understanding of the present disclosure and constitute a part of this specification, serve to explain the invention together with the following detailed description of embodiments of the invention, and do not constitute a limitation to the present disclosure. In the drawings:

FIG. 1 is a schematic structural diagram of a shift register unit in the related art;

FIG. 2 is a schematic structural diagram of a shift register unit in the implementation of the present disclosure;

FIG. 3 is a schematic diagram of the specific structure of a shift register unit in the implementation of the present disclosure;

FIG. 4 is an operation timing chart of the shift register unit shown in FIG. 3;

FIG. 5 is a schematic structural diagram of a gate drive circuit provided by the present disclosure; and

FIG. 6 is an operation timing chart of the gate drive circuit shown in FIG. 5.

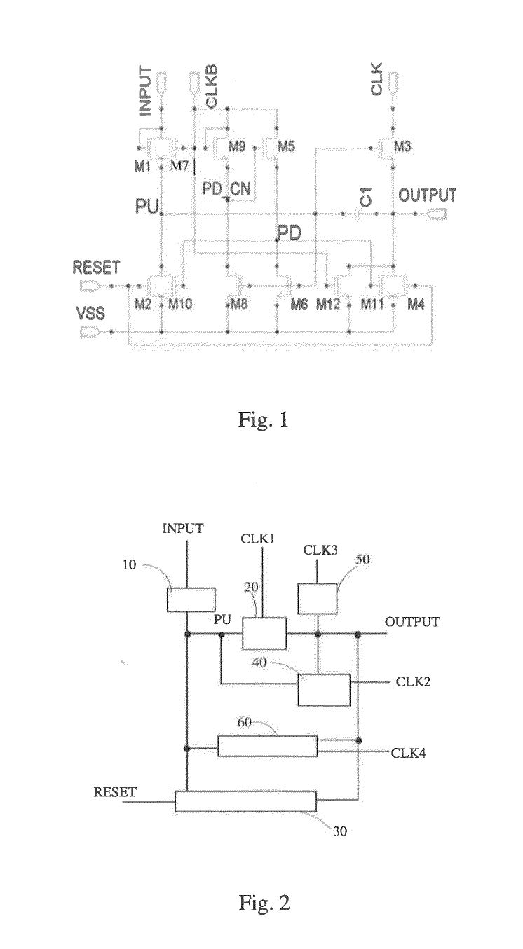

Therein, reference signs are as follows: 10, input module; 20, output module; 30, reset module; 40, pull-down module; 50, first noise reduction module; 60, second noise reduction module; PU, pull-up node; OUTPUT, output terminal; INPUT, input terminal; T1, first thin film transistor; T2, second thin film transistor; T3, third thin film transistor; T4, fourth thin film transistor; T5, fifth thin film transistor; T6, sixth thin film transistor; T7, seventh thin film transistor; T8, eighth thin film transistor; T9, ninth thin film transistor; CLK1, first clock signal terminal; CLK1′: first clock signal generating line; CLK2, second clock signal terminal; CLK2′: second clock signal generating line; CLK3: third clock signal terminal; CLK3′: third clock signal generating line; CLK4, fourth clock signal terminal; CLK4′, fourth clock signal generating line; STV, initial signal generating line.

### DETAILED DESCRIPTION OF EMBODIMENTS OF THE INVENTION

The specific mode for carrying out the present disclosure will be detailed below in conjunction with the drawings. It should be understand that the embodiments described here is merely used for illustrating and explaining the present disclosure, without limiting the present disclosure.

As a first aspect of the present disclosure, there is provided a shift register unit, comprising an input module 10, an output module 20, a reset module 30 and a pull-down module 40, where the input module 10 is configured to receive an input signal at a precharge phase and outputting the input signal to a pull-up node PU; the output module 20 is configured to output a first clock signal of a first clock signal terminal CLK1 to an output terminal OUTPUT of the shift register unit according to a potential of the pull-up node PU at an output phase; the reset module 30 is configured to pull down the potentials of the pull-up node PU and the output terminal OUTPUT of the shift register unit according to a reset signal at a reset phase; and, the pull-down module 40 is configured to pull down the potentials of the pull-up node PU and the output terminal of the shift register unit according to a second clock signal of a second clock signal terminal CLK2 at a pull-down phase, wherein the first clock signal terminal CLK1 only provides the first clock signal of a high level to the output module 20 at the output phase, and the second clock signal terminal CLK2 only provides the second clock signal of a high level to the pull-down module 40 at the reset phase or the pull-down phase.

As shown in FIG. 2, the input module 10 can be connected with the input signal terminal INPUT and the pull-up node PU, respectively, and at a precharge phase of the operation of the shift register unit (i.e., t1 phase in FIG. 4), the input signal is at a high level, the input module 10 is on, the input signal of the high level is output to the pull-up node PU through the input module 10, thus charging the pull-up node PU; the output module 20 is connected with the first clock signal terminal CLK1, the pull-up node PU and the output terminal OUTPUT of the shift register unit, respectively, and at an output phase (i.e., t2 phase in FIG. 4), the pull-up node PU is kept at the high level, the output module 20 is on, and the first clock signal terminal CLK1 provides a first clock signal of a high level, thus allowing the output terminal OUTPUT of the shift register unit to output a high level; the reset module 30 is connected with a reset terminal RESET, a low level input terminal VSS, the pull-up node PU and the output terminal OUTPUT, respectively, and at a reset phase (i.e., t3 phase in FIG. 4), the reset signal of the reset terminal RESET is at a high level, the reset module 30 is on, the pull-up node PU and the output terminal OUTPUT both are connected' with the low level input terminal VSS, thus pulling down the levels of the pull-up node PU and the output terminal OUTPUT, so as to discharge the pull-up node PU and the output terminal OUTPUT.

In case of cascading a plurality of shift register units, when a reset signal of a high level is input to a certain level shift register unit at the reset phase, the output terminal of the next level shift register unit outputs a high level signal.

In the present disclosure, the pull-down module 40 can be controlled directly by a second clock signal of the second clock signal terminal CLK2, and by adjusting the first clock signal terminal CLK1 and the second clock signal terminal CLK2, the first clock signal terminal CLK1 is only allowed to output a high level at the output phase, thus the output terminal OUTPUT outputs a high level at the output phase, while outputs a low level at the time other than the output phase. When the second clock signal terminal CLK2 only provides a high level at the reset phase, the pull-down module 40 and the reset module 30 discharge the pull-up node PU and the output terminal OUTPUT together at the reset phase, while in the other phases such as the precharge phase, the pull-down module 40 is off to avoid affecting the potentials of the pull-up node PU and the output terminal OUTPUT; likewise, when the second clock signal terminal CLK2 only outputs a high level at the pull-down phase, the pull-down module 40 discharges the pull-up node PU and the output terminal OUTPUT at the pull-down phase, thus after the pull-up node PU and the output terminal OUTPUT are reset, they discharge the pull-up node PU and the output terminal OUTPUT continuously, until the output terminal OUTPUT outputs a high level again to initiate a gate line corresponding to the shift register unit so as to reduce noise.

In the related art, the first clock signal terminal and the second clock signal terminal keep outputting high levels alternately, so in order to achieve the function of the shift register unit, it needs to provide a pull-down control module, and control the pull-down module based on the second clock signal, thus making the structure of the shift register unit relatively complicated. Whereas, the second clock signal terminal in the present disclosure can control directly the pull-down module, and thus the function of the shift register unit can be achieved only by adjusting the first clock signal and the second clock signal, allowing the pull-down module to have a function that the pull down can be achieved only by having a simple structure, so that the shift register unit has a relatively simple structure, thereby being able to achieve design of a narrow border. Compared to the related art, the time during which the first clock signal terminal and the second clock signal terminal provide high levels is shortened, thus shortening the on time of the thin film transistor in the shift register unit, prolonging the lifecycle, and mitigating the threshold voltage drifting phenomenon of the thin film transistor.

It needs to indicate that, the high level signal acts as an initiating signal, and accordingly, the thin film transistors in the following are all N type thin film transistors.

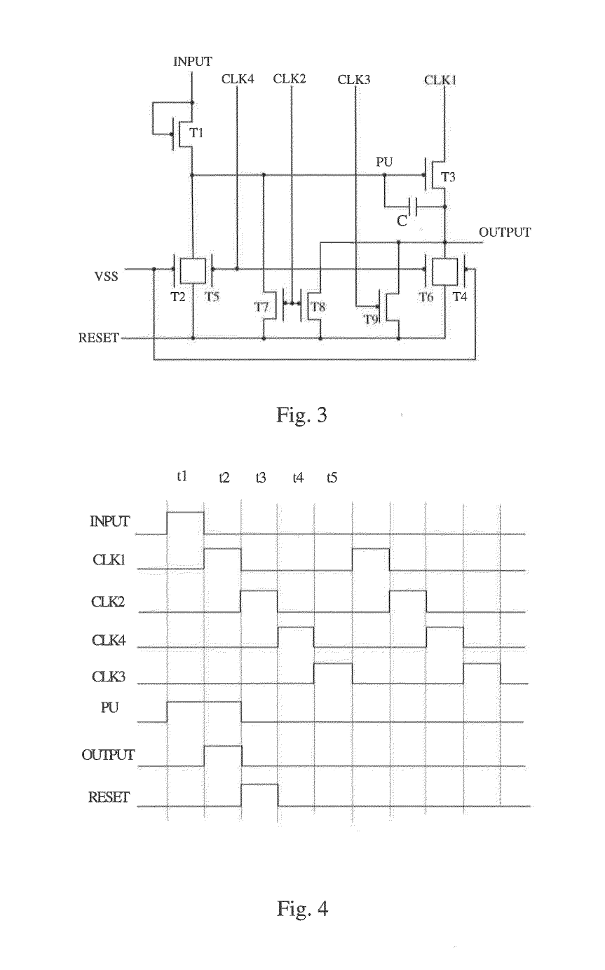

As a specific implementation of the present disclosure, as shown in FIG. 3, the input module 10 comprises a first thin film transistor T1, where the gate and first electrode of the first thin film transistor T1 are both connected with the input terminal INPUT of the shift register unit, and the second electrode of the first thin film transistor T1 is connected with the pull-up node PU. At the precharge phase, the input terminal INPUT is input a high level, and the first thin film transistor T1 is on, thus charging the pull-up node PU.

The output module 20 may comprises a third thin film transistor T3 and a capacitor C, where the gate of the third thin film transistor T3 is connected with the pull-up node PU, the first electrode of the third thin film transistor T3 is connected with the first clock signal terminal CLK1, and the second electrode of the third thin film transistor T3 is connected with the output terminal OUTPUT of the shift register unit; and the first terminal of the capacitor C is connected with the pull-up node PU, and the second terminal of the capacitor C is connected with the output terminal OUTPUT of the shift register unit. At the output phase, the second clock signal terminal CLK2 outputs a high level, the third thin film transistor T3 is ON, the bootstrap effect of the capacitor C allows the potential of the pull-up node PU to be further pulled up, and the output terminal OUTPUT outputs a high level.

The reset module 30 may comprise a second thin film transistor T2 and a fourth thin film transistor T4, where the gate of the second thin film transistor T2 is connected with the reset terminal RESET of the shift register unit, the first electrode of the second thin film transistor T2 is connected with the pull-up node PU, and the second electrode of the output module 20 is connected with a low level input terminal VSS. At the reset phase, the reset terminal RESET is input a reset signal of a high level, and the second thin film transistor T2 is on, to discharge the pull-up node PU, while the fourth thin film transistor T4 is on to discharge the output terminal OUTPUT.

More specifically, as shown in FIG. 3, the pull-down module 40 comprises a seventh thin film transistor T7 and a eighth thin film transistor T8, where the gate of the seventh thin film transistor T7 is connected with the second clock signal terminal CLK2, the first electrode of the seventh thin film transistor T7 is connected with the pull-up node PU, and the second electrode of the eighth thin film transistor T8 is connected with the low level input terminal VSS.

The gate of the eighth thin film transistor T8 is connected with the second clock signal terminal CLK2, the first electrode of the eighth thin film transistor T8 is connected with the output terminal OUTPUT of the shift register unit, and the second electrode of the eighth thin film transistor T8 is connected with the low level input terminal VSS.

At the pull-down phase (t4 phase shown in FIG. 4), the second clock signal terminal CLK2 is input a high level, both the seventh thin film transistor T7 and the eighth thin film transistor T8 are on, and the pull-up node PU communicates with the low level input terminal VSS through the seventh thin film transistor T7, thus allowing the level of the pull-up node PU to be pulled down; and, the output terminal OUTPUT communicates with the low level input terminal VSS through the eighth thin film transistor T8, thus allowing the potential of the output terminal OUTPUT to be pulled down. Further, as shown in FIG. 2, the shift register unit further comprises a third clock signal terminal CLK3 and a first noise reduction module 50, where the first noise reduction module 50 is connected with the third clock signal terminal CLK3, the output terminal OUTPUT of the shift register unit and the low level input terminal VSS, respectively, for pulling down the voltage of the output terminal OUTPUT of the shift register unit based on a third clock signal of the third clock signal terminal CLK3 at a noise reduction phase (i.e., t5 phase shown in FIG. 3) subsequent to the pull-down phase; where, the third clock signal terminal CLK3 only provides a third clock signal of a high level to the first noise reduction module 50 only at the noise reduction phase. The t1-t5 phases as shown in FIG. 4 are such five operation phases of the shift register unit in the present disclosure as the precharge phase, the output phase, the reset phase, the pull-down phase and the noise reduction phase, respectively. At the noise reduction phase, the third clock signal is at a high level, the first noise reduction module 50 is on, to discharge the pull-up node PU and the output terminal OUTPUT of the shift register unit, so as to ensure the potential of the output terminal OUTPUT to be pulled down after outputting a high level at the output phase, thus preventing noise from occurring; and, because the third clock signal is at a low level at other phases than the noise reduction phase, the potentials of the pull-up node PU and the output terminal OUTPUT at other phases will not be effected.

Specifically, as shown in FIG. 3, the first noise reduction module 50 may comprise a ninth thin film transistor T9, where the gate of the ninth thin film transistor T9 is connected with the third clock signal terminal CLK3, the first electrode of the ninth thin film transistor T9 is connected with the output terminal OUTPUT, and the second electrode of the ninth thin film transistor T9 is connected with the low level input terminal VSS. At the noise reduction phase, the third clock signal terminal CLK3 is input a high level, allowing the ninth thin film transistor T9 to be on, thus discharging the output terminal OUTPUT.

Further, as shown in FIG. 2, the shift register unit further comprises a second noise reduction module 60 and a fourth clock signal terminal CLK4, where the second noise reduction module 60 is connected with the fourth clock signal terminal CLK4, the pull-up node PU, the output terminal OUTPUT of the shift register unit and the low level input terminal VSS, for pulling down the levels of the pull-up node PU and the output terminal OUTPUT of the shift register unit based on a fourth clock signal of the fourth clock signal terminal CLK4 at the pull-down phase; where, the second clock signal terminal CLK2 only provides a second clock signal of a high level to the pull-down module 40 at the reset phase, and the fourth clock signal terminal CLK4 only provides a fourth clock signal of a high level to the second noise reduction module 60 at the pull-down phase.

When a plurality levels of shift register units are connected in series to constitute a shift register, the input terminal INPUT of the first level shift register unit is input a high level at the precharge level, and the first clock signal terminal CLK1, the second clock signal terminal CLK2, the third clock signal terminal CLK3 and the fourth clock signal terminal CLK4 of each level of shift register unit are input high levels at different phases, therefore, the duty cycles of the first clock signal, the second clock signal, the third clock signal and the fourth clock signal provided to the whole shift register are 25%, while both the duty cycles of the first clock signal and the second clock signal in the related art are 50%. In contrast, the on time of the thin film transistor in the shift register unit in the present disclosure is reduced relatively, lengthening the lifecycle of the thin film transistor.

Specifically, as shown in FIG. 3, the second noise reduction module 60 comprises a fifth thin film transistor T5 and sixth thin film transistor T6,

the gate of the fifth thin film transistor T5 is connected with the fourth clock signal terminal CLK4, the first electrode of the fifth thin film transistor T5 is connected with the pull-up node UP, and the second electrode of the fifth thin film transistor T5 is connected with the low level input terminal VSS; and

the gate of the sixth thin film transistor T6 is connected with the fourth clock signal terminal CLK4, the first electrode of the sixth thin film transistor T6 is connected with the output terminal OUTPUT of the shift register unit and the second electrode of the sixth thin film transistor T6 is connected with the low level input terminal VSS.

At the pull-down phase, the fourth clock signal terminal CLK4 is input a high level, and the fifth thin film transistor T5 is on, thus discharging the pull-up node PU, while the sixth thin film transistor T6 is on, thus discharging the output terminal OUTPUT.

The operation process of the shift register unit will be described below in conjunction with FIG. 3 and FIG. 4.

At the precharge phase (i.e., t1 phase), the input terminal INPUT is input a high level, each of the first clock signal terminal CLK1, the second clock signal terminal CLK2, the third clock signal terminal CLK3 and the fourth clock signal terminal CLK4 is input a low level, at which time, the first thin film transistor T1 is on, other thin film transistors are all off, the input terminal INPUT charges the pull-up node PU through the first thin film transistor T1, and the output terminal OUTPUT outputs a low level.

At the output phase (i.e., t2 phase), the first clock signal terminal CLK1 is input a high level, and each of the input terminal INPUT, the second clock signal terminal CLK2, the third clock signal terminal CLK3 and the fourth clock signal terminal CLK4 is input a low level, at which time, the first thin film transistor T1 is off, the potential of the pull-up node PU is pulled up under the bootstrap effect of the capacitor C; and the third thin film transistor T3 is on, and the output terminal OUTPUT outputs a high level.

At the reset phase (i.e., t3 phase), the second clock signal terminal CLK2 is input a high level, and each of the input terminal INPUT, the first clock signal terminal CLK1, the third clock signal terminal CLK3 and the fourth clock signal terminal CLK4 is input a low level, at which time, the seventh thin film transistor T7 and the eighth thin film transistor T8 are on, thus discharging the pull-up node PU and the output terminal OUTPUT; in the meantime, at this phase, the reset terminal RESET is input a high level signal (i.e., the output terminal of the next level shift register unit outputs a high level) signal, and the second thin film transistor T2 and the fourth thin film transistor T4 are on, thus ensuring the pull-up node PU and the output terminal are at low levels. At the pull-down phase (i.e., t4 phase), the fourth clock signal terminal CLK4 is input a high level signal, and each of the input terminal INPUT, the first clock signal terminal CLK1, the second clock signal terminal CLK2 and the third clock signal terminal CLK3 is input a low level signal, at which time, the fifth thin film transistor T5 and the sixth thin film transistor T6 are on, to continually discharge the pull-up node PU and the output terminal OUTPUT, thus allowing the output terminal OUTPUT to output a stable low level.

At the noise reduction phase (i.e., t5 phase), the third clock signal terminal CLK3 is input a high level signal, and each of the input terminal INPUT, the first clock signal terminal CLK1, the second clock signal terminal CLK2, and the fourth clock signal terminal CLK4 is input a low level signal, at which time, the ninth thin film transistor T9 is on, to discharging the output terminal OUTPUT, allowing the output terminal OUTPUT to output a stable low level, to avoid interference of noise.

When a plurality of shift register units are cascaded, as shown in FIG. 6, at t1 phase, the input terminal INPUT1 of the first level shift register unit is input a high level signal; at t2 phase, the output terminal OUTPUT1 of the first level shift register unit outputs a high level signal, while the input terminal INPUT2 of the second level shift register unit is input a high level signal; at t3 phase, the output terminal OUTPUT2 of the second level shift register unit outputs a high level signal, while the reset terminal RESET1 of the first level shift register unit and the input terminal INPUT3 of the third level shift register unit are input high level signals; at t4 phase, the output terminal OUTPUT3 of the third level shift register unit outputs a high level signal while the reset terminal RESET2 of the second level shift register unit and the input terminal INPUT4 of the fourth level shift register unit are input high level signals; and at t5 phase, the output terminal OUTPUT4 of the fourth level shift register unit is input a high level signal while the reset terminal RESET3 of the third shift register unit and the input terminal of the fifth level shift register unit are input high level signals; and so on.

As a second aspect of the present disclosure, there is provided a shift register, comprising at least three levels of shift register units, which are the above mentioned shift register units. In the adjacent three levels of shift register units, the output terminal of the second level shift register unit is connected with the input terminal of the third level shift register unit and the reset terminal of the first level shift register unit.

It can be seen that, in the present disclosure, by adjusting the time sequence of the first clock signal and the second clock signal, the pull-down module is made to implement the discharge for the pull-up node and the output terminal under the direct control of the second clock signal, thus allowing the shift register unit to have a simple structure. It can be seen from the above mentioned description, the shift register unit can only comprise 9 thin film transistors and one capacitor. Compared to the related art, the structure of the shift register unit in the present disclosure is more simple, the potentials of the pull-up node and the output terminal are controlled, respectively, through such four clock signals as the first clock signal, the second clock signal, the third clock signal and the fourth clock signal, so the duty cycle of each clock signal is 25%, thus allowing the on time of the thin film transistors to be shortened, the life cycles of the thin film transistors to be lengthened and the threshold voltage drifting phenomenon of the thin film transistors to be mitigated.

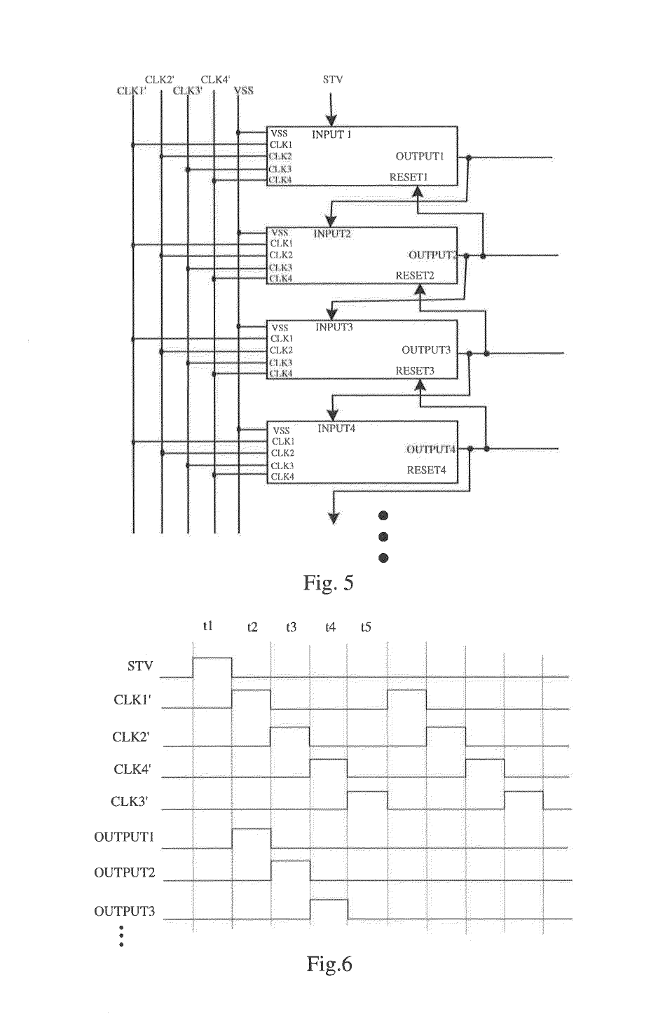

As a third aspect of the present disclosure, there is provided a gate drive circuit, comprising a shift register which comprises the above mentioned shift register units provided by the present disclosure. As shown in FIG. 5, the gate driving circuit further comprises a first clock signal generating line CLK1′ and a second clock signal generating line CLK2′, where the first clock signal generating line is connected with the first clock signal terminal of the shift register unit, the second clock signal generating line is connected with the second clock signal terminal of the shift register unit, the first clock signal line only provides a first clock signal of a high level at the output phase, the second clock signal line only provides a second clock signal of a high level to the shift register unit at the reset phase or the pull-down phase.

As shown in FIG. 5, the shift register may comprise a plurality levels of shift register units, the first clock signal terminal of each shift register unit is connected with the first clock signal generating line CLK1′, and the second clock signal terminal of each shift register unit is connected with the second clock signal generating line CLK2′.

It is to be understood that the time of the output phase of each level shift register unit is different, the first clock signal provided by the first clock signal generating line CLK1′ is a continuous signal, and the output phase of each shift register unit is at a high level. Each of the time of the reset phase and the time of the pull-down phase of each shift register unit are also different from each other, the second clock signal provided by the second clock signal generating line CLK2′ at the reset phase of each level shift register unit is at a high level, or, the second clock signal provided by the second clock signal generating line CLK2′ is at a high level at the pull-up phase of each level shift register unit.

As mentioned above, the shift register unit further comprises a third clock signal terminal and a first noise reduction module, which is connected with the third clock signal terminal, the output terminal of the shift register unit and the low level input terminal, for pulling down the potential of the output terminal of the shift register unit according to a third clock signal of the third clock signal terminal at a noise reduction phase subsequent to the pull-down phase; and as shown in FIG. 5, the gate drive circuit further comprises a third clock signal generating line CLK3′ which is connected with the third clock signal terminal,

where, the third clock signal generating line CLK3′ only provides a third clock signal of a high level to the third clock signal terminal at the noise reduction phase. And similar to the first clock signal generating line CLK1′, the third clock signal provided by the third clock signal generating line CLK3′ is at a high level at the noise reduction phase of each level shift register unit.

The shift register unit further comprises a fourth clock signal terminal and a second noise reduction module, which is connected with the fourth clock signal terminal, the pull-up node, the output terminal of the shift register unit and the low level input terminal, for pulling down the potentials of the pull-up node and the output terminal of the shift register unit according to a fourth clock signal of the fourth clock signal terminal at the pull-down phase; the gate drive circuit further comprises a fourth clock signal generating line CLK4′ which is connected with the four clock signal terminal, where the second clock signal generating line CLK2′ only provides a second clock signal of a high level to the second clock signal terminal at the reset phase, and the fourth clock signal terminal CLK4′ only provides a fourth clock signal of a high level to the fourth clock signal terminal at the pull-down phase. I.e., the fourth clock signal is at a high level at the pull-down phase of each level shift register unit.

It can be understood that the gate driving circuit further comprises an initial signal providing line STV for providing an initial signal, as shown in FIG. 5, the initial signal providing line STV being connected with the output terminal of the first level shift register unit in the shift register. Although the gate drive circuit of the present disclosure has two clock signal generating lines added compared to the related art, the structure of each level shift register unit is simplified, so the structure of the gate drive circuit is simplified wholly. The timing chart of the gate drive circuit is as shown in FIG. 6, and because the operation time sequence of a plurality of cascaded shift register units has been described in the above, it will not be mentioned here again.

As a fourth aspect of the present disclosure, there is provided a display device comprising the above mentioned gate drive circuit.

It is appreciated that the above embodiments are merely exemplary embodiments used to illustrate the principles of the present disclosure, but the present disclosure is not limited thereto. Those of ordinary skill in the art can make various changes and modifications without departing from the spirit and essence of the present disclosure, and such changes and modifications are also considered as being within the scope of the invention.

1. A shift register unit, comprising:
an input module configured to receive an input signal at a precharge phase and outputting the input signal to a pull-up node;
an output module configured to output a first clock signal of a first clock signal terminal to an output terminal of the shift register unit according to a potential of the pull-up node at an output phase;
a reset module configured to pull down the potentials of the pull-up node and the output terminal of the shift register unit according to a reset signal at a reset phase; and
a pull-down module configured to pull down the potentials of the pull-up node and the output terminal according to a second clock signal of a second clock signal terminal at a pull-down phase,
wherein the first clock signal terminal only provides the first clock signal of a high level to the output module at the output phase, and the second clock signal terminal only provides the second clock signal of a high level to the pull-down module at the reset phase or the pull-down phase.

2. The shift register unit according to claim 1, wherein the pull-down module includes a seventh thin film transistor and an eighth thin film transistor,
the gate of the seventh thin film transistor is connected with the second clock signal terminal, the first electrode of the seventh thin film transistor is connected with the pull-up node, and the second electrode of the seventh thin film transistor is connected with a low level input terminal;
the gate of the eighth thin film transistor is connected with the second clock signal terminal, the first electrode of the eighth thin film transistor is connected with the output terminal of the shift register unit, and the second electrode of the eighth thin film transistor is connected with the low level input terminal.

3. The shift register unit according to claim 1, wherein the shift register unit further comprises a third clock signal terminal and a first noise reduction module, which is connected with the third clock signal terminal, the output terminal of the shift register unit and the low level input terminal, configured to pull down the potential of the output terminal of the shift register unit according to a third clock signal of the third clock signal terminal at a noise reduction phase subsequent to the pull-down phase;
wherein the third clock signal terminal only provides the third clock signal of a high level to the first noise reduction module at the noise reduction phase.

4. The shift register unit according to claim 3, wherein the first noise reduction module includes a ninth thin film transistor, the gate of the ninth thin film transistor is connected with the third clock signal terminal, the first electrode of the ninth thin film transistor is connected with the output terminal of the shift register unit, and the second electrode of the ninth thin film transistor is connected with the low level input terminal.

5. The shift register unit according to claim 3, wherein the shift register unit further comprises a fourth clock signal terminal and a second noise reduction module, which is connected with the fourth clock signal terminal, the pull-up node, the output terminal of the shift register unit and the low level input terminal, configured to pull down the potentials of the pull-up node and the output terminal of the shift register unit according to a fourth clock signal of the fourth clock signal terminal at the pull-down phase,
the second clock signal terminal only provides the second clock signal of a high level to the pull-down module at the reset phase, and the fourth clock signal terminal only provides the fourth clock signal of a high level to the second noise reduction module at the pull-down phase.

6. The shift register unit according to claim 5, wherein the pull-down module includes a fifth thin film transistor and a sixth thin film transistor,
the gate of the fifth thin film transistor is connected with the fourth clock signal terminal, the first electrode of the fifth thin film transistor is connected with the pull-up node, and the second electrode of the fifth thin film transistor is connected with the low level input terminal;
the gate of the sixth thin film transistor is connected with the fourth clock signal terminal, the first electrode of the sixth thin film transistor is connected with the output terminal of the shift register unit, and the second electrode of the sixth thin film transistor is connected with the low level input terminal.

7. The shift register unit according to claim 6, wherein the input module includes a first thin film transistor, both the gate and the first electrode of the first thin film transistor are connected with the input terminal of the shift register unit, and the second electrode of the first thin film transistor is connected with the pull-up node.

8. The shift register unit according to claim 6, wherein the output module includes a third thin film transistor and a capacitor,
the gate of the third thin film transistor is connected with the pull-up node, the first electrode of the third thin film transistor is connected with the first clock signal terminal, and the second electrode of the third thin film transistor is connected with the output terminal of the shift register unit;
the first terminal of the capacitor is connected with the pull-up node, and the second terminal of the capacitor is connected with the output terminal of the shift register unit.

9. The shift register unit according to claim 6, wherein the reset module includes a second thin film transistor and a fourth thin film transistor,
the gate of the second thin film transistor is connected with the reset terminal of the shift register unit, the first electrode of the second thin film transistor is connected with the pull-up node, and the second electrode of the second thin film transistor is connected with the low level input terminal;
the gate of the fourth thin film transistor is connected with the reset terminal of the shift register unit, the first electrode of the fourth thin film transistor is connected with the output terminal of the shift register unit, and the second electrode of the fourth thin film transistor is connected with the low level input terminal.

10. A shift register, wherein it comprises at least three levels of shift register units, each of the shift register unit, comprising:
an input module configured to receive an input signal at a precharge phase and outputting the input signal to a pull-up node;
an output module configured to output a first clock signal of a first clock signal terminal to an output terminal of the shift register unit according to a potential of the pull-up node at an output phase;
a reset module configured to pull down the potentials of the pull-up node and the output terminal of the shift register unit according to a reset signal at a reset phase; and
a pull-down module configured to pull down the potentials of the pull-up node and the output terminal according to a second clock signal of a second clock signal terminal at a pull-down phase,
wherein the first clock signal terminal only provides the first clock signal of a high level to the output module at the output phase, and the second clock signal terminal only provides the second clock signal of a high level to the pull-down module at the reset phase or the pull-down phase.
where in adjacent three levels of shift register units, the output terminal of the second level shift register unit are connected with the input terminal of the third level shift register unit and the reset terminal of the first level shift register unit, respectively.

11. The shift register according to claim 10, wherein the pull-down module includes a seventh thin film transistor and an eighth thin film transistor,
the gate of the seventh thin film transistor is connected with the second clock signal terminal, the first electrode of the seventh thin film transistor is connected with the pull-up node, and the second electrode of the seventh thin film transistor is connected with a low level input terminal;
the gate of the eighth thin film transistor is connected with the second clock signal terminal, the first electrode of the eighth thin film transistor is connected with the output terminal of the shift register unit, and the second electrode of the eighth thin film transistor is connected with the low level input terminal.

12. The shift register according to claim 10, wherein the shift register unit further comprises a third clock signal terminal and a first noise reduction module, which is connected with the third clock signal terminal, the output terminal of the shift register unit and the low level input terminal, configured to pull down the potential of the output terminal of the shift register unit according to a third clock signal of the third clock signal terminal at a noise reduction phase subsequent to the pull-down phase;
wherein the third clock signal terminal only provides the third clock signal of a high level to the first noise reduction module at the noise reduction phase.

13. The shift register unit according to claim 12, wherein the first noise reduction module includes a ninth thin film transistor, the gate of the ninth thin film transistor is connected with the third clock signal terminal, the first electrode of the ninth thin film transistor is connected with the output terminal of the shift register unit, and the second electrode of the ninth thin film transistor is connected with the low level input terminal.

14. The shift register according to claim 12, wherein the shift register unit further comprises a fourth clock signal terminal and a second noise reduction module, which is connected with the fourth clock signal terminal, the pull-up node, the output terminal of the shift register unit and the low level input terminal, configured to pull down the potentials of the pull-up node and the output terminal of the shift register unit according to a fourth clock signal of the fourth clock signal terminal at the pull-down phase,
the second clock signal terminal only provides the second clock signal of a high level to the pull-down module at the reset phase, and the fourth clock signal terminal only provides the fourth clock signal of a high level to the second noise reduction module at the pull-down phase.

15. The shift register according to claim 14, wherein the pull-down module includes a fifth thin film transistor and a sixth thin film transistor,
the gate of the fifth thin film transistor is connected with the fourth clock signal terminal, the first electrode of the fifth thin film transistor is connected with the pull-up node, and the second electrode of the fifth thin film transistor is connected with the low level input terminal;
the gate of the sixth thin film transistor is connected with the fourth clock signal terminal, the first electrode of the sixth thin film transistor is connected with the output terminal of the shift register unit, and the second electrode of the sixth thin film transistor is connected with the low level input terminal.

16. The shift register unit according to claim 15, wherein the input module includes a first thin film transistor, both the gate and the first electrode of the first thin film transistor are connected with the input terminal of the shift register unit, and the second electrode of the first thin film transistor is connected with the pull-up node.

17. A gate drive circuit, wherein it comprises a shift register that comprises a shift register unit, the shift register unit, including:
an input module configured to receive an input signal at a precharge phase and outputting the input signal to a pull-up node;
an output module configured to output a first clock signal of a first clock signal terminal to an output terminal of the shift register unit according to a potential of the pull-up node at an output phase;
a reset module configured to pull down the potentials of the pull-up node and the output terminal of the shift register unit according to a reset signal at a reset phase; and
a pull-down module configured to pull down the potentials of the pull-up node and the output terminal according to a second clock signal of a second clock signal terminal at a pull-down phase,
wherein the first clock signal terminal only provides the first clock signal of a high level to the output module at the output phase, and the second clock signal terminal only provides the second clock signal of a high level to the pull-down module at the reset phase or the pull-down phase.
wherein the gate drive circuit further comprises a first clock signal generating line and a second clock signal generating line, where the first clock signal generating line is connected with the first clock signal terminal of the shift register unit, the second clock signal generating line is connected with the second clock signal terminal of the shift register unit, the first clock signal generating line only provides a first clock signal of a high level at an output phase, and the second clock signal generating line only provides a second clock signal of a high level to the shift register unit at a reset phase or a pull-down phase.

18. The gate drive circuit according to claim 17, wherein the shift register unit further comprises a third clock signal terminal and a first noise reduction module, which is connected with the third clock signal terminal, the output terminal of the shift register unit and a low level input terminal, configured to pull down the potential of the output terminal of the shift register unit according to a third clock signal of the third clock signal terminal at a noise reduction phase subsequent to the pull-down phase; and, the gate drive circuit further comprises a third clock signal generating line which is connected with the third clock signal terminal,
wherein, the third clock signal generating line only provides a third clock signal of a high level to the third clock signal terminal at a noise reduction phase.

19. The gate drive circuit according to claim 18, wherein the shift register unit further comprises a fourth clock signal terminal and a second noise reduction module, which is connected with the fourth clock signal terminal, the pull-up node, the output terminal of the shift register unit and the low level input terminal, configured to pull down the potentials of the pull-up node and the output terminal of the shift register unit according to a fourth clock signal of the fourth clock signal terminal at the pull-down phase; and, the gate drive circuit further comprises a fourth clock signal generating line which is connected with the fourth clock signal terminal,
the second clock signal generating line only provides a second clock signal of a high level to the second clock signal terminal at a reset phase, and the fourth clock signal generating line only provides a fourth clock signal of a high level to the fourth clock signal terminal at a pull-down phase.
